(19) United States
(12) Patent Application Publication
(10) Pub. No.: US 2015/0298490 A1
(43) Pub. Date: Oct. 22, 2015

(54) DISPLAY DEVICE AND DISPLAY SYSTEM USING THE SAME

(71) Applicant: Yoshihiro TAKECHI, Tokyo (JP)

(72) Inventor: Yoshihiro TAKECHI, Tokyo (JP)

(21) Appl. No.: 14/368,244

(22) PCT Filed: Dec. 27, 2011
(86) PCT No.: PCT/JP2011/080235

§ 371 Date: Jun. 23, 2014

(51) Int. Cl. B43L 1/00; B43L 5/00; G09B 5/02; B43L 1/04; H05K 5/00; H05K 5/02

(52) U.S. Cl. CPC B43L 1/00; H05K 5/0017; H05K 5/0247; G09B 5/02; B43L 1/04; B43L 5/00

(57) ABSTRACT

A display device includes a display device a display panel (e.g. a blackboard or a whiteboard) juxtaposed in a frame. The rear face of the display device is covered by a cover having a height and a planar part. It is possible to selectively attach a reversible I/O unit and a reversible option slot unit to either the right side end or the left side end in the planar part of the rear face of the display device in such a way that input/output terminals are directed to the exterior of the display device. Additionally, an air outlet and an air inlet are formed in the surface of the option slot unit opposite to the rear face joining the planar part of the rear face of the display, thus securing air ventilation. The display device having user friendliness can be easily manufactured using standardized parts with a low manufacturing cost.

### TECHNICAL FIELD

The present invention relates to a display device having a liquid crystal panel, and a display system juxtaposing the display device with a display board such as a white board and a black board.

### BACKGROUND ART

Recently, various types of information display devices have been generally and widely used. For this reason, teachers who explain contents of lectures using characters and pictures in school lessons and lectures may increasingly tend to display and explain various pieces of information with display devices having touch panels instead of blackboards and whiteboards or with computers, tablet terminals, or slate PCs connected to display devices. In particular, it is possible to explain characters and pictures written on display screens of touch panels with display devices having touch-panel display screens.

As a generally-known display device, for example, Patent Literature Document 1 discloses a flat liquid display device in which input/output terminals used to switch the display screen or used to turn ON or OFF are fixedly aligned on the side face of the display screen.

FIG. 15 is an illustration of the rear face of a generally-known display device. For example, a display device 100 includes a control part 101, which is used to drive the display screen on a control substrate disposed on the rear face of the liquid-crystal display screen and which is covered by a cover 102. A center area 102a of the cover 102, which is used to cover the control part 101 disposed at the center of the rear face, is protruded from the surrounding area. Additionally, input/output terminals 103 and 104 are attached to a side face 102b and a lower face 102c in the center area 102a, and therefore they are connectable to terminals of power cords and communication wiring cords.

Recently, display devices such as liquid crystal panels have been juxtaposed with blackboards or whiteboards in rectangular frames, and therefore it is possible to make explanations by alternatively using pictures of display devices and handwritten descriptions of blackboards or whiteboards. When teachers explain lessons and lectures by use of the display system, it is possible to make supplemental explanations with handwritings, as necessary, while displaying clear and detailed still pictures and moving pictures; hence, the display system is convenient to deepen understanding of pupils and students.

### CITATION LIST

### Patent Literature Document

Patent Literature Document 1: Japanese Patent Application Publication No. 2004-109396

### SUMMARY OF INVENTION

### Technical Problem

When a teacher makes an explanation using a liquid-crystal display device, for example, it is possible to assume that a teacher is standing at a regular position or at a preferable position for explanation in proximity to one side of the display device while input/output terminals are attached to the opposite side of the display device. It is troublesome for a teacher to operate input/output terminals because a teacher may hardly operate them at his/her standing position.

In the display device 100 shown in FIG. 15 in which the input/output terminals 103 and 104 are attached to the side face 102b and the lower face 102c in the center area 102a forming a height on the rear face, it is troublesome for each user to detachably attach terminals of power cords and wiring cords to the terminals 103 and 104, and it is difficult for each user to operate switches. When a display device is juxtaposed with a blackboard or a whiteboard, a teacher who is standing at one side of a display device may not operate input/output terminals disposed on the other side close to a blackboard or a whiteboard unless a teacher turns around the rear side. Additionally, a teacher who is standing in proximity to a blackboard or a whiteboard is further distanced from input/output terminals, and therefore it is further troublesome for a teacher to operate them with the display device having low user-friendliness.

In the above display device, powder of chalks used to write characters on a blackboard or a whiteboard may be scattered and enter into speakers or gaps between a display monitor and a bezel, thus causing problems with the display device.

The present invention is made in consideration of the above problem, and it is an object of the invention to provide a user-friendly display device and a display system using it.

### Solution to Problem

The present invention is directed to a display device including a display part having a display screen and a control part which is disposed in the rear face of the display part so as to drive the display part. The display device is characterized by further including an input/output unit, having an input/output terminal, which is detachably and selectively attached to either one side end or other side end in the rear face of the display device, wherein the input/output unit is positioned in such a way that the input/output terminal thereof is directed to the exterior of the display device even when the input/output unit is attached to either the one side end or the other side end.

The display device of the present invention is designed to install the input/output unit at the side end close to the standing position even when the standing position of a presenter who explains the displayed content of the display device is either the right side or the left side of the display device, wherein the input/output terminal is directed to the exterior of the input/output unit; hence, it is convenient for each user to easily operate the input/output unit and the display device in proximity to each user's position. Additionally, it is possible to set up the same input/output unit selectively in either the right side or the left side of the display device; thus, it is possible to standardize parts so as to reduce the manufacturing cost. In this connection, the side ends indicate the ends in the right and left directions in the rear face of the display device, but the side ends may embrace the ends in the upper and lower directions.

It is preferable that the input/output unit be an I/O unit having the input/output terminal. This makes it easy for each user to operate the display device since the operation switches and input/output terminals are collectively stored in the I/O unit.

It is preferable that the input/output unit be an option slot unit having an additional control device and the input/output terminal. It is possible for the display device to demonstrate multiple functions by use of the option slot unit which may install an additional control device such as a computer having a storage device, a tablet terminal, and a slate PC.

It is preferable that a wiring cord be used to connect the input/output unit to the display device, wherein a cover used to cover the wiring cord is selectively attached depending on the attached position of the input/output unit. It is possible to prevent the other person from touching or playing with a wiring cord by covering a wiring cord when a wiring cord connectable to the display device is arranged with respect to an I/O unit or an option slot unit which is attached to the rear face of the display device.

It is possible to attach the I/O unit by reversing the front and the rear. By reversing the front and the rear of the I/O unit which is attached to either the right side end or the left side end, it is possible to position the input/output terminal being directed to the exterior in either case. By arranging another wiring cord in the rotary axial direction of the I/O unit, it is possible to prevent the wiring cord from interfering with other parts since the position of the wiring cord is unchanged irrespective of the front/rear reversal.

It is possible to form an air inlet and/or an air outlet in the face of the option slot unit other than the face joining the display device in such a way that the option slot unit is rotatable in the face joining the display device. By reversing the upper and lower faces of the option slot unit which is attached to either the right side end or the left side end, it is possible to reliably secure air ventilation since the air inlet and/or the air outlet is not positioned in the face joining the display device. It is preferable that the air inlet and/or the air outlet be formed on the surface opposite to the face joining the display device.

The present invention is directed to a display system juxtaposing a display board and a display device including a display part having a display screen and a control part which is disposed in a rear face so as to drive the display part. The display system is characterized by further including an input/output unit, having an input/output terminal, which is selectively and detachably attached to either one side end or other side end in the rear face of the display device, wherein the input/output unit is attached to the side end opposite to the display board in such a way that the input/output terminal is formed in the side face opposite to the display board.

According to the present invention, it is possible to attach the input/output unit to the side end in the rear face of the display device at the position opposite to and separated from the display board even when the display system employs either a left-side combination or a right-side combination in terms of the arrangement of the display device and the display board such as a blackboard and a whiteboard. Thus, it is convenient for each user to easily operate the display system since the input/output terminal of the input/output unit is placed close to the standing position of a presenter who makes an explanation while standing by the display device. Additionally, it is possible to standardize parts so as to reduce the manufacturing cost since the same input/output terminal can be selectively attached to either the right side end or the left side end.

It is preferable that the input/output unit be an I/O unit having the input/output terminal. Additionally, it is preferable that the input/output unit be an option slot unit having an additional control device and the input/output terminal.

It is possible to arrange a wiring cord used to connect the input/output unit to the display device, wherein a cover used to cover the wiring cord is selectively attached depending on the attached position of the input/output unit.

It is possible to selectively attach the I/O unit to either one side end or other side end by reversing the front and the rear thereof. Additionally, it is possible to form an air inlet and/or an air outlet in the face of the option slot unit other than the face joining the display device, wherein the option slot unit is selectively attached to either one side end or other side end of the display device by reversing the upper face and the lower face thereof.

The present invention is directed to a display device including a display part having a display screen and a control part which is disposed in the rear face of the display part so as to drive the display part. The display device is characterized by interpose a dustproof member between display screen and a bezel covering the proximity of the ridges of the display screen. According to the present invention, it is possible to prevent dust from entering the display screen by means of the dustproof member.

It is preferable that the dustproof member be interposed between the bezel and a touch sensor unit which is disposed in proximity to the ridges in the front face of the display screen.

Additionally, it is possible to form the dustproof member by use of a band-shaped member having a cushioning property and elasticity, or it is possible to form the dustproof member by use of a urethane. It is possible to reliably secure protection against dust with high airtightness due to clamping using the dustproof member serving as a band-shaped member having a cushioning property and elasticity.

### Advantageous Effects of Invention

In the display device and the display system using it according to the present invention, an input/output unit is attached to the side end of the display device in proximity to the standing position of each user who uses the display device and the display system while input/output terminals are positioned externally; hence, it is possible to improve usability facilitating easy operation on input/output terminals positioned close to each user. In particular, it is possible to further improve usability with the display system juxtaposing the display device and the display board.

Even when either one side or the other side is selected differently as the side end joining the input/output unit, it is possible to arrange input/output terminals close to each user by reversing the input/output unit. Since input/output units are each standardized using common parts in an adaptable manner to either case, it is possible to easily manage parts of input/output units, thus reducing the manufacturing cost and the management cost of parts.

### BRIEF DESCRIPTION OF DRAWINGS

FIG. 1 is a schematic illustration of a bidirectional communication display system using a display system according to an embodiment of the present invention.

FIG. 2 is a schematic illustration of a network cloud connected to the display system of the present embodiment.

FIG. 3 is a front view of the display system of the present embodiment.

FIG. 4 is a front view of the display system shown in FIG. 3 in which the display device is positioned on the left side.

FIG. 5 is an exploded perspective view regarding the rear face of the display device used in the display system.

FIG. 6 is a rear perspective view of the display device shown in FIG. 5 in which an I/O unit and an option slot unit are attached to one side end of the rear face.

FIG. 7 is a rear perspective view of the display device in which an I/O unit and an option slot unit are attached to the other side end.

FIG. 8 includes schematic illustrations before and after the reversal of the front and the rear of the I/O unit.

FIG. 9 is a perspective view of a speaker unit in view of the front face of a bracket.

FIG. 10 is an exploded perspective view in view of the rear face of the speaker unit.

FIG. 11 is a cross-sectional view of the speaker unit shown in FIG. 10 taken along line A-A.

FIG. 12 is an exploded perspective view of the display device including a dustproof unit disposed close to the display monitor.

FIG. 13 is a cross-sectional view of the display device along its center.

FIG. 14 is an enlarged view of an area B of the display device shown in FIG. 13.

FIG. 15 is a perspective view of the rear face of the conventional display device.

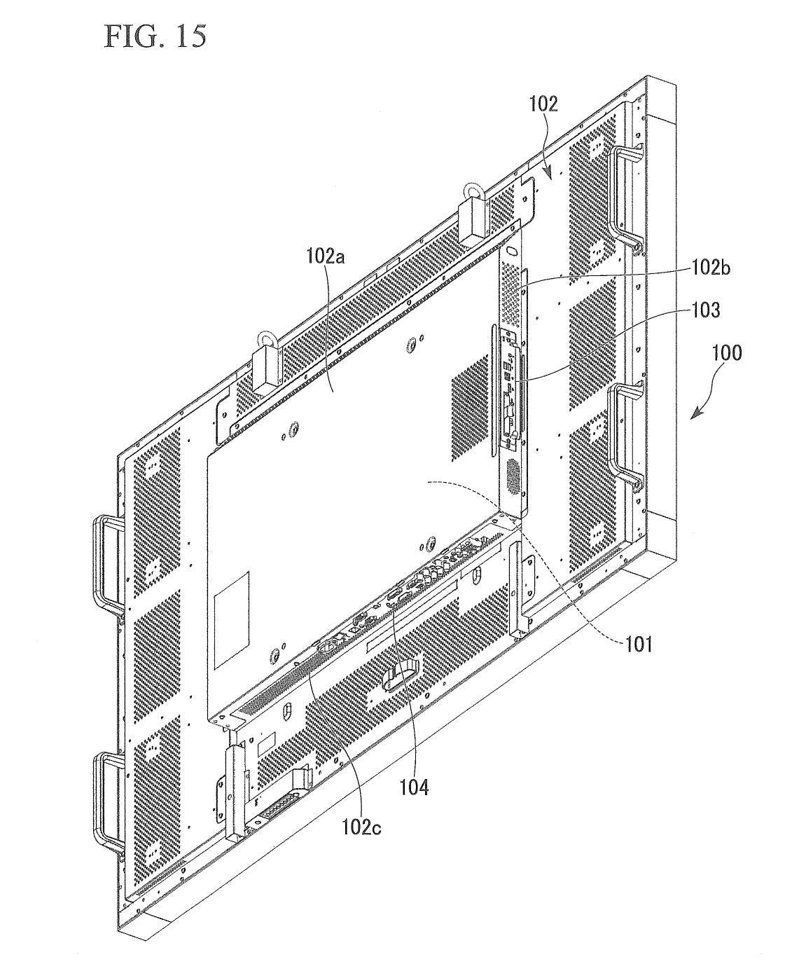

### DESCRIPTION OF EMBODIMENT

Hereinafter, the embodiment of the present invention will be described with reference to the accompanying drawings.

A display system 1 according to the embodiment of the present invention can be used as an electronic blackboard. It is possible to input various pieces of information with a display device 2 of the display system 1 which is connected to a LAN to mutually communicate with each other, or it is possible to transmit the display information of the display system 1 which is connected to another display or a printer.

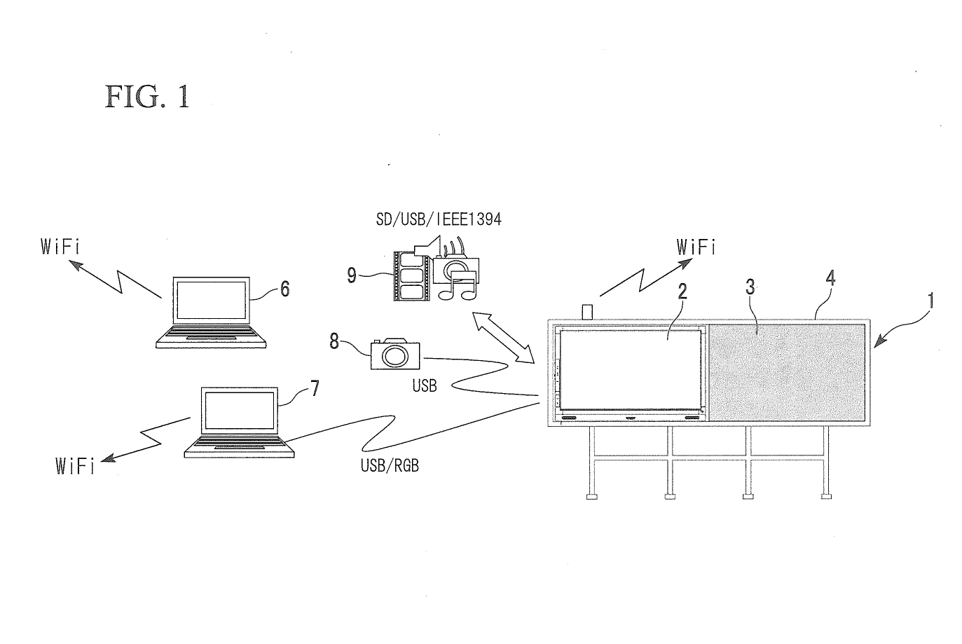

For example, FIG. 1 shows an interactive whiteboard system serving as the display system 1 in which the display device 2 such as a liquid-crystal display device is juxtaposed with a blackboard 3 and installed in a frame 4. For example, the display device 2 is equipped with a touch panel. The display device 2 is wirelessly and mutually connected to display devices 6 and 7 having WiFi units, a camera 8, and a supply device 9 used to supply moving pictures and music information, thus mutually transmitting or receiving various pieces of information; hence, it is possible to display various pieces of information on the display device 2 which may be used for lessons and lectures in schools, laboratories, and companies.

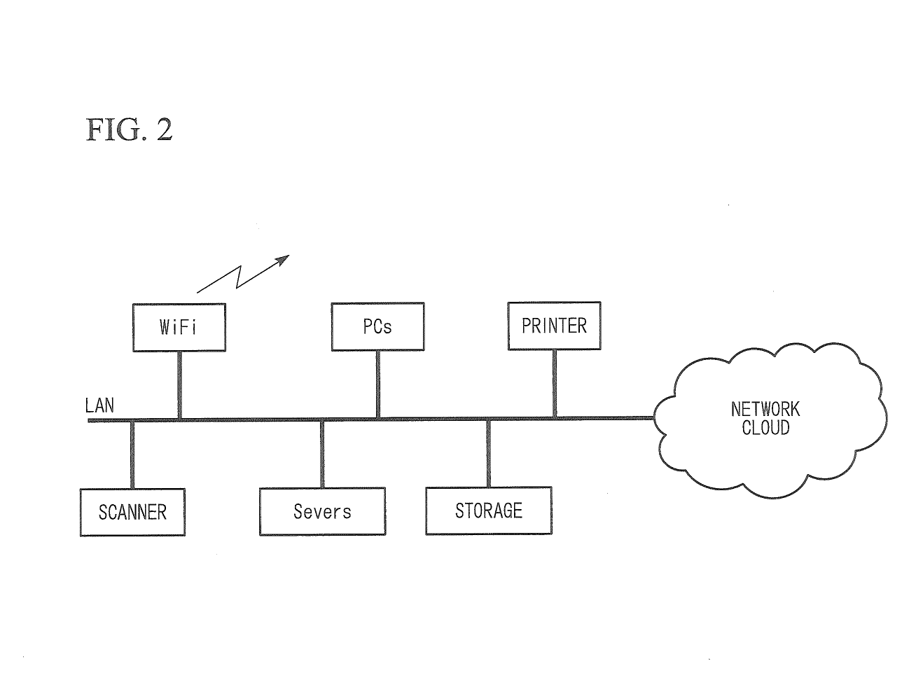

FIG. 2 shows the Internet cloud system in which display devices, WiFi units, scanners, personal computers, servers, printers, and storage units are connected to various communication devices via wireless LANs and wired LANs, thus allowing schools, laboratories, and companies to transmit or receive various pieces of information while displaying screen images and printing out information. Thus, it is possible for WiFi units to wirelessly transmit information of various communication devices to the display device 2 of the display system 1, and it is possible transmit the display information of the display system 1 to various communication devices so as to display or output the information.

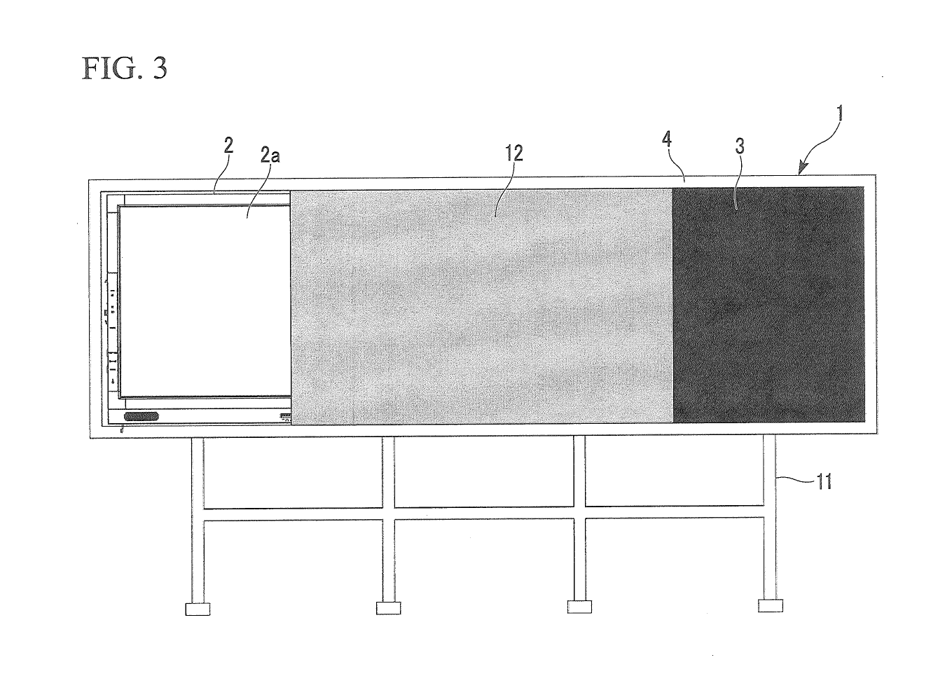

Next, the display system 1 used for various systems will be described with reference to FIGS. 3 to 14.

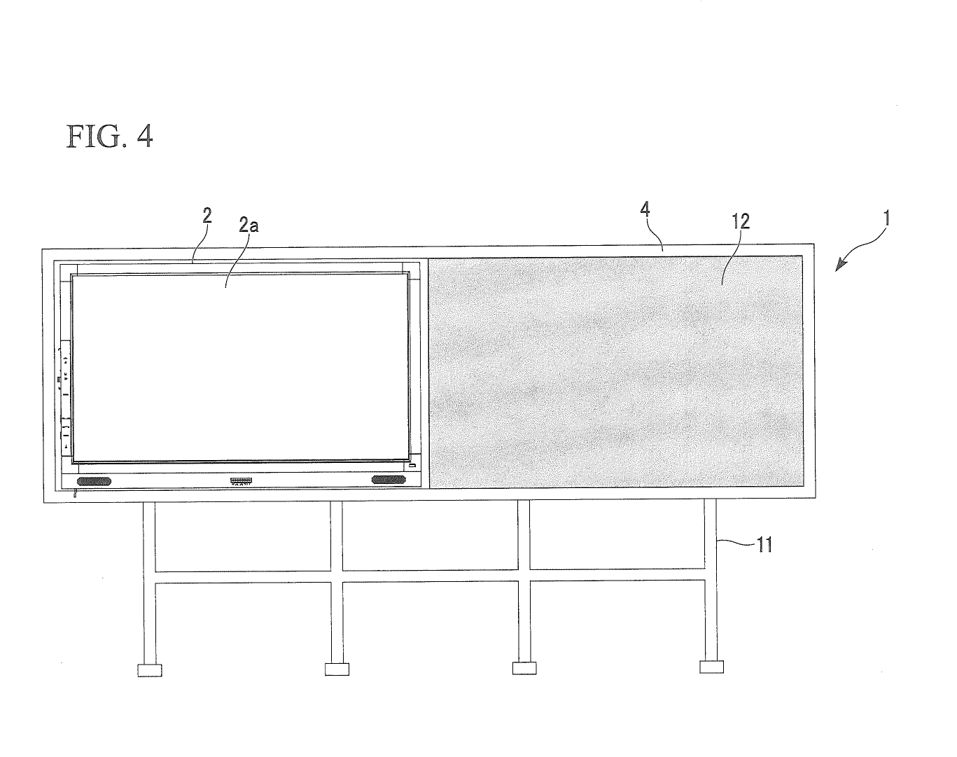

In the display system 1 shown in FIGS. 3 and 4, the display device 2 such as a liquid crystal display having a touch panel is juxtaposed with the blackboard 3 in the frame 4 having legs 11, wherein a whiteboard 12 serving as a cover of a display monitor 2a of the display device 2 can be slid along rails embedded in the frame 4 via wheels (not shown). The whiteboard 12 can be slid between the open position and the closed position of covering the display monitor 2a, wherein the whiteboard 12 covers the blackboard 3 at the open position of the display monitor 2a. In this connection, it is possible to exchange the blackboard 3 and the whiteboard 12 in the display system 1.

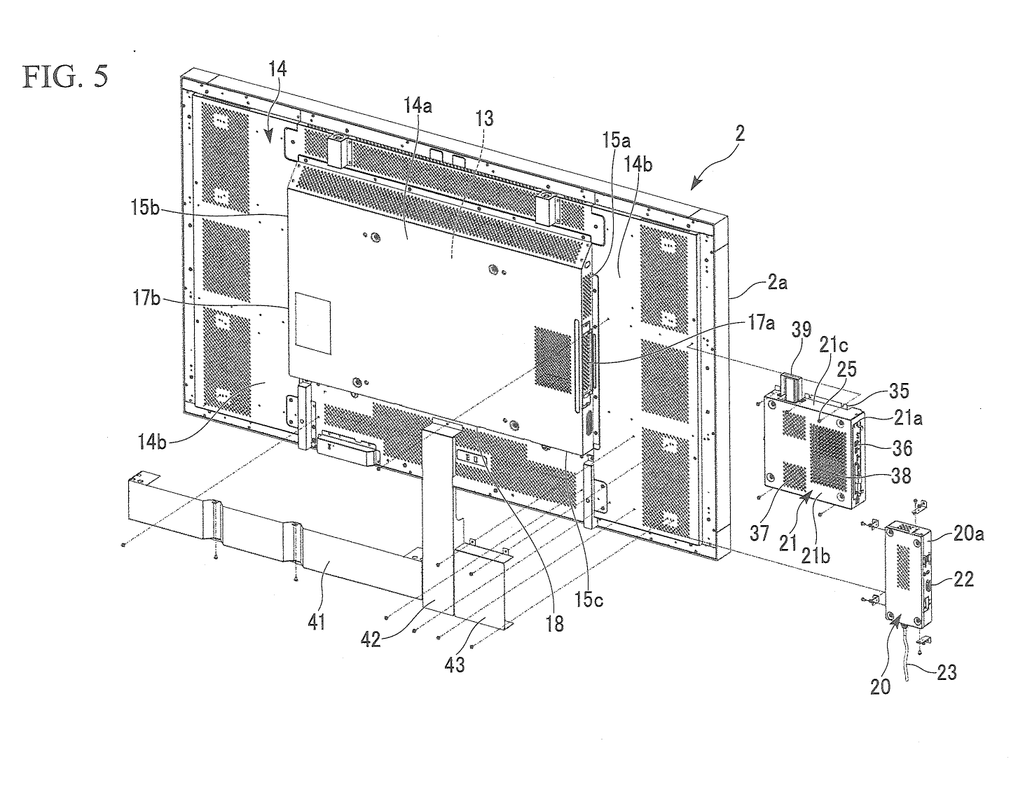

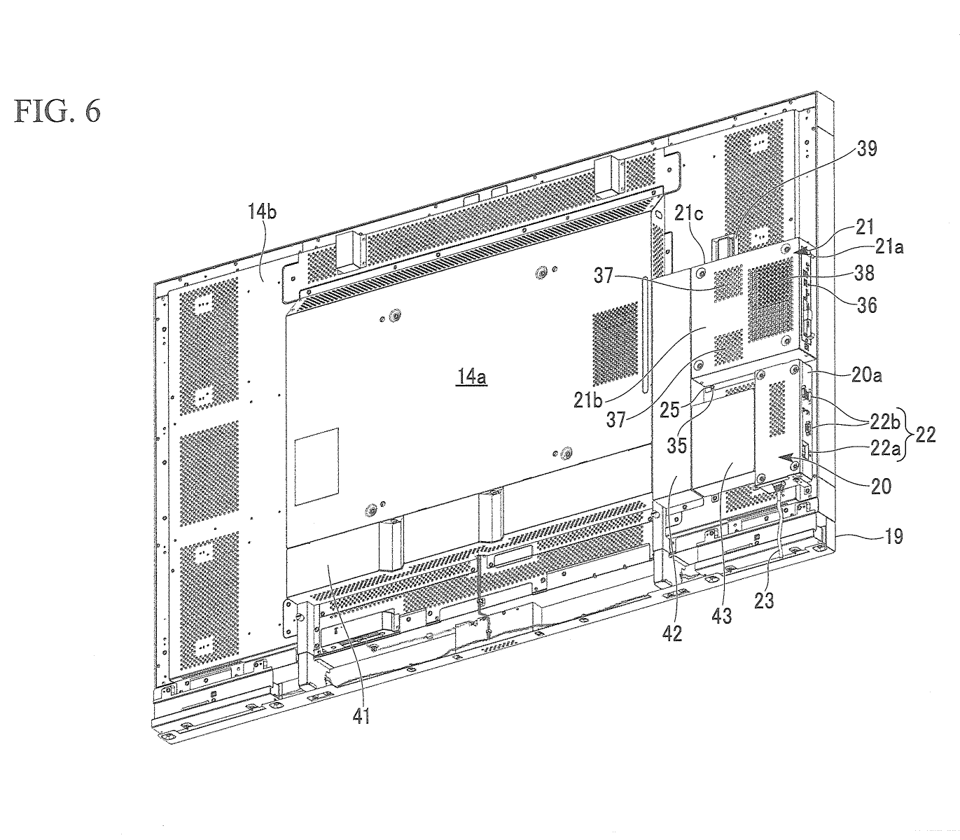

FIGS. 5 and 6 show the configuration of the rear face of the display device 2. In the specification, the front face refers to the face to arrange the display screen of the display device 2, while the rear face refers to the opposite face. In the drawings, a control part 13, which is used to drive a liquid-crystal display part of the display monitor 2a and mounted on a control substrate (not shown) attached to the rear face of the display monitor 2a of the display device 2, is attached to the center area of the rear face, wherein the rear face is entirely covered by a cover 14. As shown in FIG. 5, a height 14a protruded in the rear side is formed in the center area of the cover 14 keeping the control part 13, wherein a planar part 14b is formed in the surrounding area.

An input/output terminal 18 for the main body electrically connected to the control part 13 is attached to a lower face 15c of the height 14a. In this connection, the input/output terminal may refer to an input terminal, an output terminal, or both of input and output terminals. That is, the input/output terminal is used to transmit or receive signals with an external device positioned outside the display device.

FIG. 6 shows a speaker 19 which is extended in a width direction is installed in the lower part of the display device 2.

In FIG. 6, an I/O unit 20 including one or plural input/output terminals is disposed at the right end of the height 14a and fixed to the planar part 14b of the cover 14 via bolts 25 in the rear face of the display device 2. Additionally, an option slot unit 21, which is positioned above and adjacent to the I/O unit 20 so as to detachably install an additional control device such as a computer unit having a storage device, a tablet terminal, and a slate PC, is attached to the planar part 14b via bolts 25.

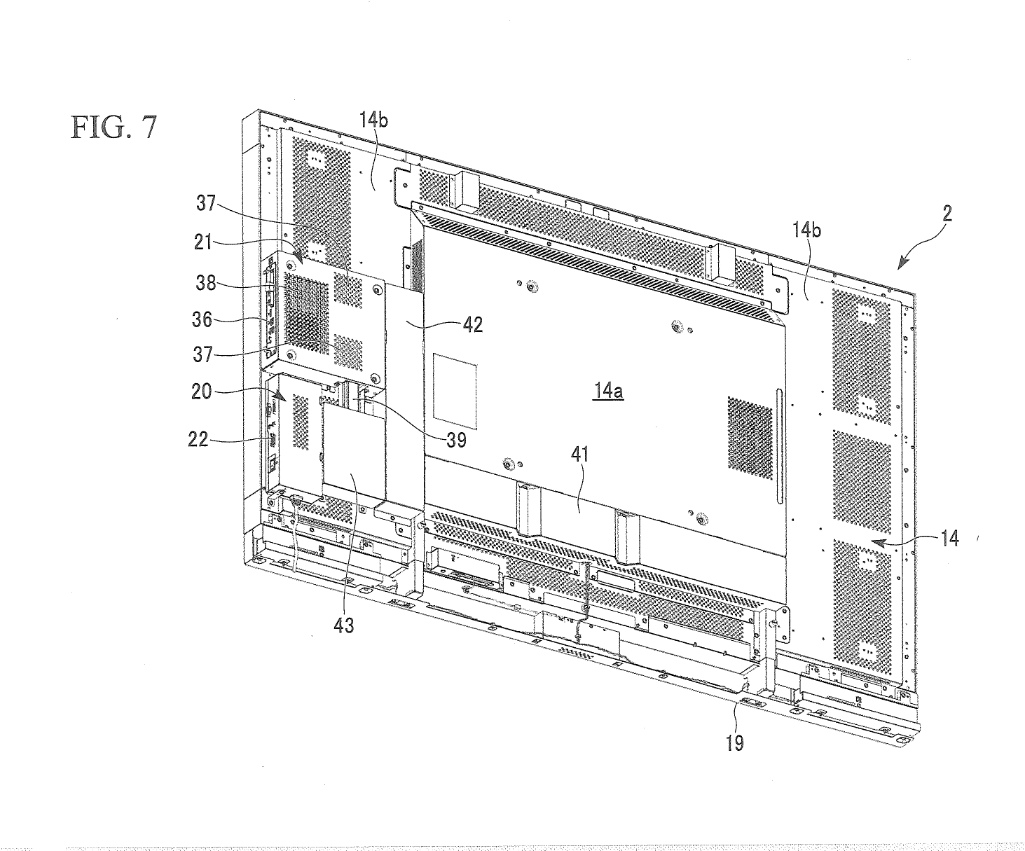

As shown in FIGS. 6 and 7, both the I/O unit 20 and the option slot unit 21 are selectively attached to the planar part 14b in the right side or the left side from the height 14a of the cover 14.

An input/output terminal 22 used for an external device, such as an operation switch 22a and a terminal 22b used to connect terminals of various wiring cords is formed in a side face 20a of the I/O unit 20 which is directed to the exterior, while a power cord 23 is attached to the lower face of the I/O unit 20. The power cord is disposed in a front/rear rotary axial direction of the I/O unit 20.

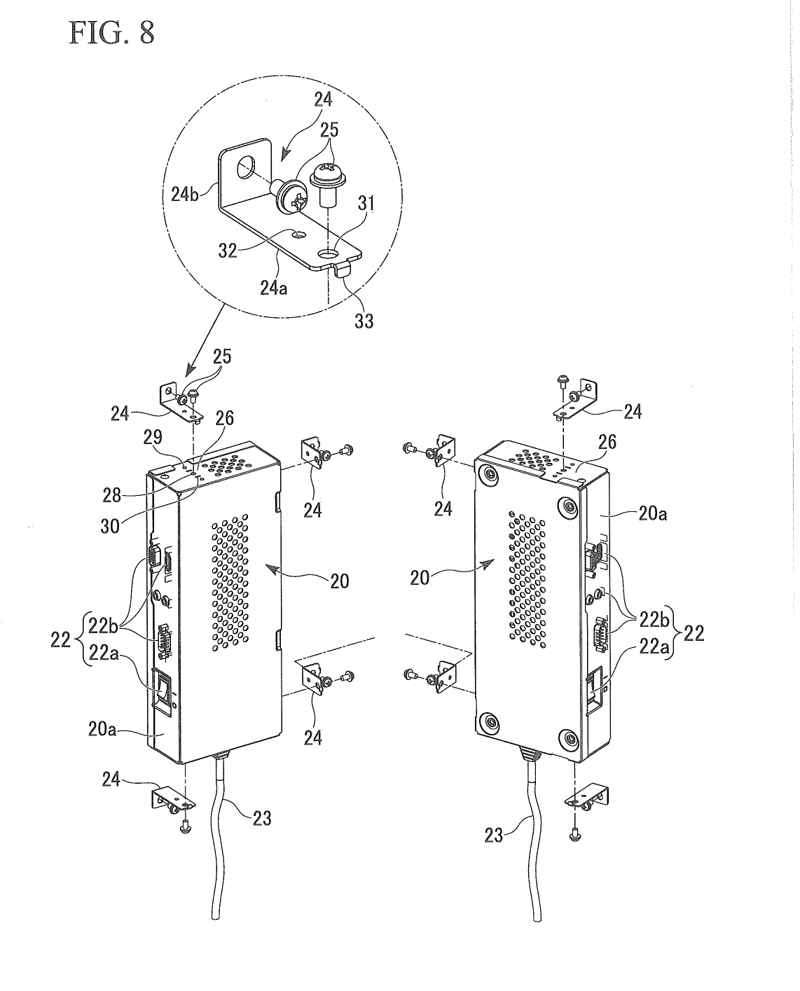

As shown in FIG. 8, when the I/O unit 20 is selectively attached to the planar part 14b in the right side or the left side from the height 14a, it is possible to reversely place the front and the rear of the I/O unit 20, thus maintaining the position of the power cord 23 disposed in the rotary axial direction. For example, the I/O unit 20 is connected to the planar part 14b of the cover 14 by means of L-shaped metal members 24 via bolts 25. The L-shaped metal member 24 includes a long element 24a and a short element 24b which are perpendicular to each other.

For example, the I/O unit 20 has a plurality of fixing positions 26 which is adapted to the metal members 24 and the bolts 25 and formed in each of three side faces other than the side face 20a arranging the input/output terminal 22. At the fixing position 26, a tapped hole 28 which can be fixed to the long element 24a of the metal member 24 is formed at the center in the thickness direction, while a boss 29 and a recess 30 are symmetrically formed beside the tapped hole 28.

A through-hole 31 which allows for insertion of the bolt 25 positioned opposite to the tapped hole 28 is formed in the long element 24a of the metal member 24 which is positioned opposite to the fixing position 26. Additionally, a rotation-preventive hole 32 engaged with the boss 29 and a positioning projection 33 engaged with the recess 30 are formed beside the through-hole 31 so as to fix the positioning. Another through-hole which allows for insertion of the bolt 25 is formed in the short element 24 of the metal member 24.

For this reason, even when the front and the rear of the I/O unit 20 are reversed by 180 degrees and attached to the planar part 14b in the right side or the left side from the height 14a of the cover 14, it is possible to bring the long element 24a of the metal member 24 in contact with the I/O unit 20 at each fixing position 26 such that the boss 29 is engaged with the hole 32 of the long element 24a, the projection 33 is engaged with the recess 30, and the bolt 25 is engaged with the tapped hole 28 via the through-hole 31. Additionally, the short element 24b is brought into contact with the planar part 14b and fixed using a bolt, thus fixing the I/O unit 20.

The option slot unit 21 is fixed to the planar part 14b by use of bolts 25 engaged with through-holes 35 formed at the corners thereof. An inlet used to insert a small personal computer and an input/output terminal 36 connectable with terminals of various wiring cords of external devices are formed in a side face 21a which is directed to the exterior. An air outlet 37 and an air inlet 38 are formed in a front face 21b which is positioned to face the planar part 14b. Additionally, a WiFi unit 39 (or a wireless LAN unit) used to wirelessly transmit or receive signals is attached to a side face 21c adjoining the side face 21a.

As shown in FIGS. 6 and 7, when the option slot unit 21 is selectively attached to the planar part 14b in the right side or the left side from the height 14a, the upper face and the lower face thereof can be reversed by 180 degrees in the same plane. Thus, even when the option slot unit 21 is positioned in either the right side or the left side of the height 14b, it is possible to place the input/output terminal 36 directed to the exterior, while it is possible to place the front face 21b having the air inlet 37 and the air outlet 38 opposite to the planar part 14b.

The input/output terminal 18 for the main body, which is formed in the lower face 15c of the height 14a, the I/O unit 20, and the option slot unit 21 are connected to wiring cords (not show).

As shown in FIGS. 5 to 7, wiring cords placed in the lower part of the height 14a are covered by a first cable cover 41; wiring cords interposed between the option slot unit 21 and the height 14a are covered by a second cable cover 42; wiring cords interposed between the second cable cover 42 and the I/O unit 20 are covered by a third cable cover 43.

To change the positions of wiring cords between the case of FIG. 6 in which the I/O unit 20 and the option slot unit 21 are placed in the right side of the height 14a and the case of FIG. 7 in which the I/O unit 20 and the option slot unit 21 are placed in the left side of the height 14a, it is necessary to shift the second cable cover 42 and the third cable cover 43 in parallel so as to fix them via bolts 25.

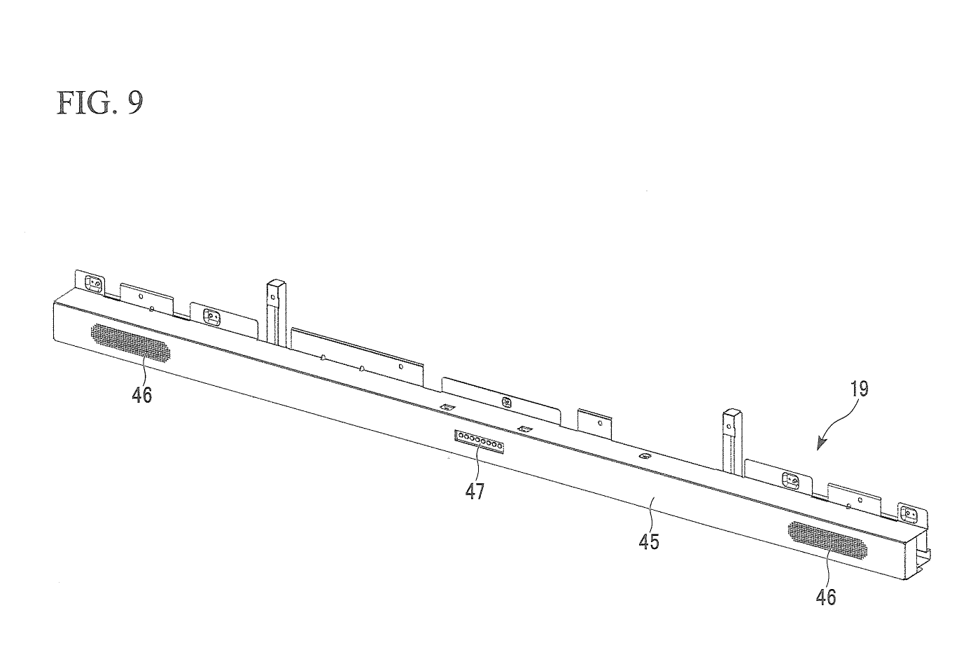

Next, the speaker device 19 will be described with reference to FIGS. 9 to 11.

The speaker device 19 is disposed below the display monitor 2a arranged in the front face of the display device 2. FIG. 9 shows the exterior shape of the speaker device 19 in view of the front face. The speaker device 19 has a box-shaped speaker bracket 45 with a pair of output parts 46 having punching apertures which are formed in the left and right sides on the front face, wherein a set of operation buttons 47 is formed at the center between the output parts 46.

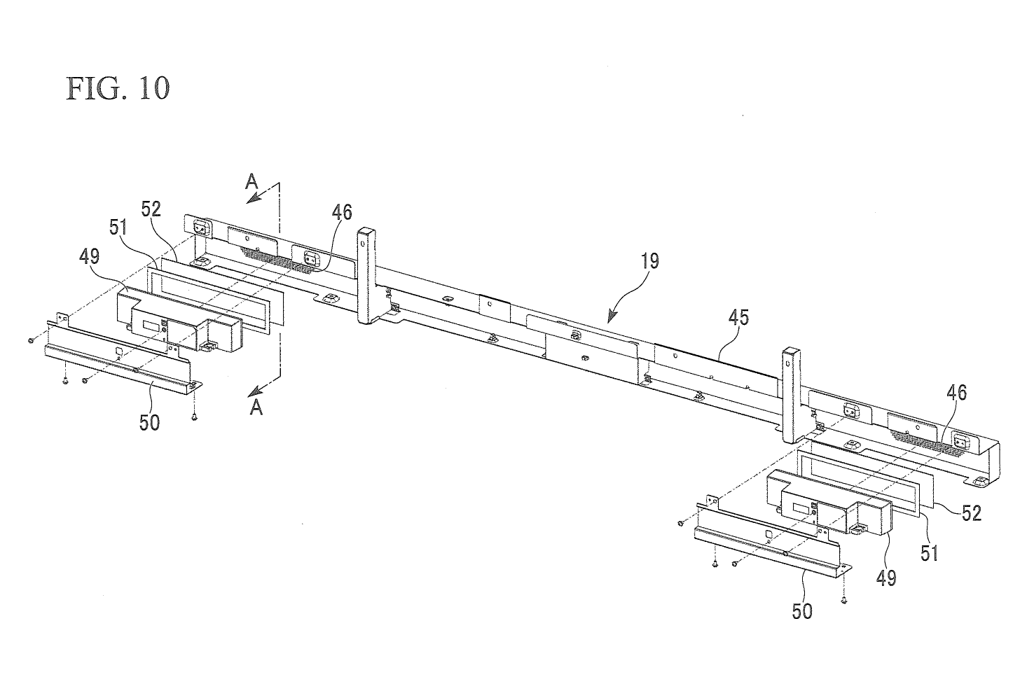

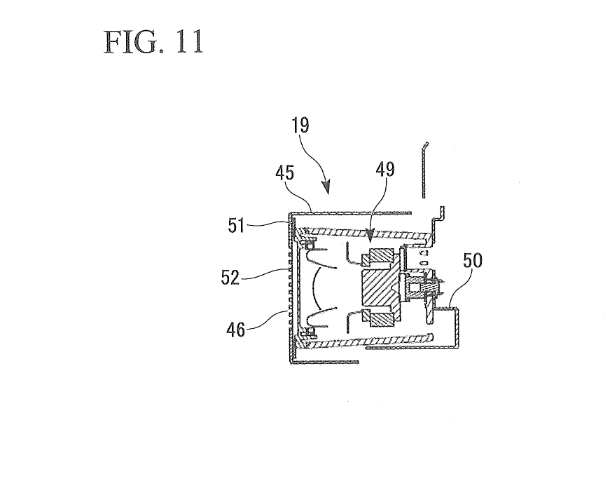

FIG. 10 is an exploded perspective view of the speaker device 19 in view of the rear face, and FIG. 11 is a cross-sectional view taken along line A-A in FIG. 10 showing a cross section being cut at the center of the output part 46. A speaker unit 49 is arranged inside of (or rearward of) the output part 46 of the speaker bracket 45, while a rear bracket 50 is attached to the rear side of the speaker unit 49. A vibration-proof sheet 51 made of a cushion having a rectangular frame shape is attached to the front face of the speaker unit 49, while a dustproof sheet 52 made of a mesh with an aperture diameter φ=0.30 mm and an aperture pitch of 0.45 mm is attached to the front face of the vibration-proof sheet 51.

In the speaker bracket 45, the dustproof sheet 52 is attached to the rear face of the output part 46 with punching apertures exerting a dust-preventing function. Thus, even when a teacher uses the display system 1, the output part 46 may transmit sound therethrough while securing dual preventive measures to prevent chalk power or dust from entering therein. Due to the insertion of the vibration-proof sheet 51 between the speaker unit 49 and the dustproof sheet 52, it is possible to absorb vibration occurring in the speaker unit 49 while preventing noise.

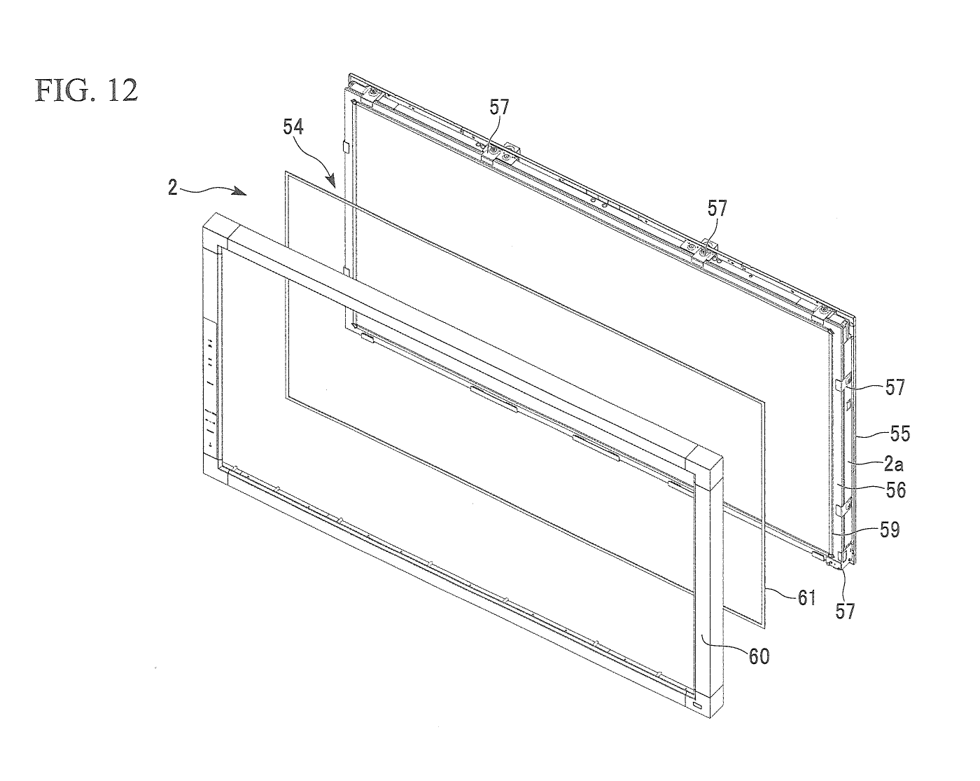

A dustproof unit 54 arranged in connection with the display monitor 2a in the front face of the display device 2 will be described with reference to FIGS. 12 to 14.

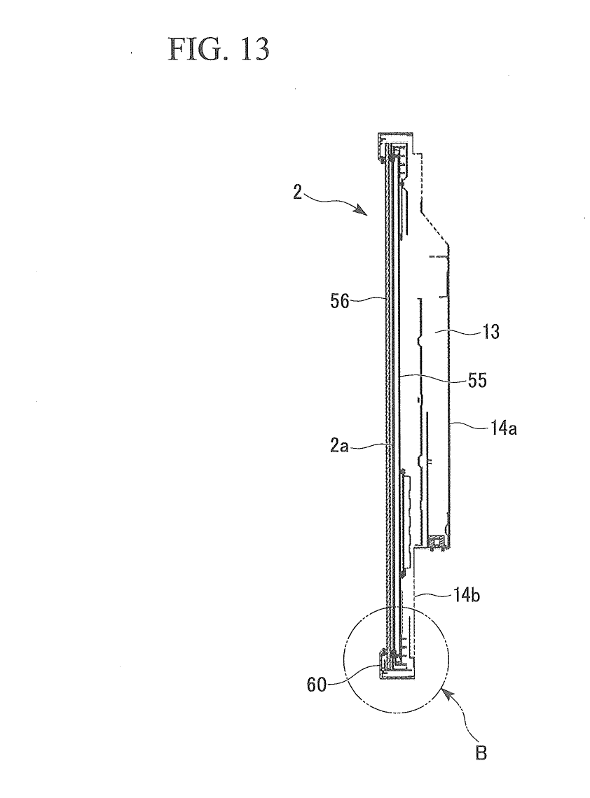

In the display device 2 shown in FIGS. 12 and 13, the display panel 2a such as a thin liquid-crystal panel is placed in the front face of a control substrate 55 having the control part 13 in its rear side, and a protective glass 56 is placed in the front face of the display monitor 2a. The three layers of materials are laminated and integrally unified together using a plurality of fixing metal members 57 attached to the ridges along the four sides. A touch sensor unit 59 configuring part of a touch sensor panel is attached to the four sides on the front face of the protective glass 56. Additionally, a frame-shaped bezel 60 is attached to the front face.

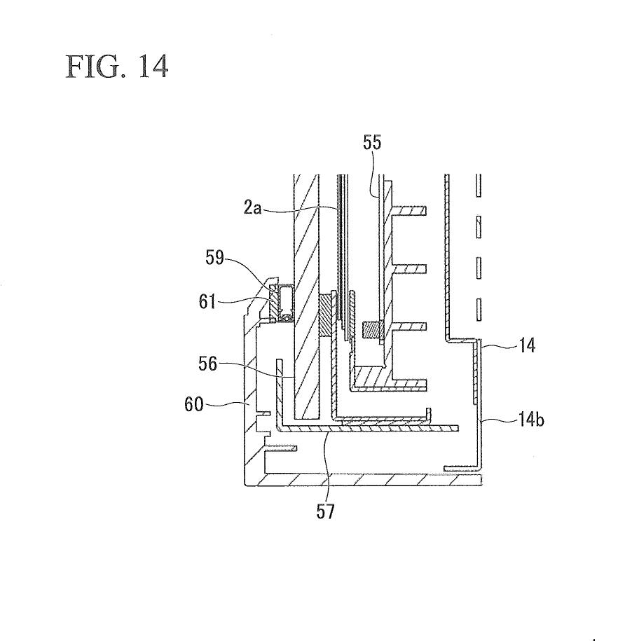

A dustproof member 61 made of a cushion material is interposed between the bezel 60 and the touch sensor unit 59 in order to prevent chalk powder or dust from entering inside the display device 2. As shown in FIG. 14, the band-shaped dustproof member 61 is laminated upon the touch sensor unit 59 since the dustproof member 61 is formed in a rectangular frame shape similar to the touch sensor unit 59. For example, the dustproof member 61 made of a urethane material is divided into four pieces of band-shaped elements along four sides.

Due to the adoption of the dustproof unit 54 having the above configuration, it is possible to prevent chalk powder or dust from entering inside the display monitor 2a by means of the dustproof member 61 interposed between the bezel 60 and the touch sensor unit 59 in the display device 2.

In the display system 1 of the present embodiment has the above configuration shown in FIGS. 3 and 4, it is necessary to determine as to whether the regular standing position of a teacher or the standing position of a teacher or a presenter due to the arrangement of desks, shelves, and fixtures in a school room is either the right side or the left side of the display system 1, thus determining the positions of the display device 2 and the blackboard 3 in the frame 4. In the rear face of the display device 2, the I/O unit 20 and the option slot unit 21 are attached to the side end of the planar part 14b, in the rearward of the blackboard 3, aside the height 14a. Thus, the side faces 20a and 21a of the I/O unit 20 and the option slot unit 21 having the input/output terminals 22 and 36 are directed to the exterior of the display device 2; that is, they are positioned at the side end spaced apart from the blackboard 3.

In order to selectively attach the I/O unit 20 to either the left side end or the right side end from the height 14a, it is necessary to install the I/O unit 20 by reversing its front and the rear. Thus, the side face 20a having the input/output terminal 22 is normally placed at the side end externally of the display device 2. Since the power cord 23 is fixed to the lower face of the I/O unit 20 irrespective of reversal of its front and the rear, it is possible to prevent the power cord 23 from interfering with other parts or from supplying power. To install the I/O unit 20, as shown in FIG. 8, the I/O unit 20 is fixed to the planar part 14 by use of the L-shaped metal member 24 by applying the bolt 25 at the fixing position 26 on the side face of the I/O unit 20.

To install the option slot unit 21, it is necessary to selectively attach the option slot unit 21 to either the right side end or the left side end from the height 14a by reversing the upper and lower faces of the option slot unit 21 in the same plane. Then, the option slot unit 21 is fixed by engaging the bolt 25 into the planar part 14b via the through-hole 35 of the housing. Since the option slot unit 21 has the air inlet 37 and the air outlet 38 on the front face 21b opposite to the rear facing the planar part 14b of the cover 14, it is possible to secure air ventilation while preventing the air inlet 37 and the air outlet 38 from being closed by the planar part 14b of the cover 14 even when the installed position of the option slot unit 21 is changed by reversing the upper and lower faces thereof.

Additionally, both the I/O unit 20 and the option slot unit 21 are selectively attached to the right side end or the left side end from the height 14a in the display device 2, while the wiring cords of the units 20 and 21 are connected to the input/output terminal 18 of the height 14a. Subsequently, the second cable cover 42 and the third cable cover 43 used to cover the wiring cords are horizontally shifted to one side face 15a of the height 14a shown in FIG. 6 or the other side face 15b of the height 14a shown in FIG. 7, and then they are fixed using the bolts 25. In this connection, it is unnecessary to change the wiring cords connected to the input/output terminal 18 formed in the lower face 15c of the height 14a; hence, it is unnecessary to move the first cable cover 41 used to cover the wiring cords.

Chalk powder or dust may be fallen down when a teacher or a presenter makes an explanation using the display system 1 while writing characters or pictures on the blackboard 3 or the whiteboard 12. Due to the punching apertures formed in the output parts 46 of the bracket 45 in the front face of the speaker unit 49 of the speaker device 19 and due to the dustproof sheet 52 disposed inside the speaker device 19, it is possible to prevent chalk powder or dust from entering into the speaker unit 49. Due to the vibration-proof sheet 51 attached to the front face of the speaker unit 49, it is possible to prevent the speaker unit 49 from generating noise due to vibration occurring in the speaker device 19. Since the dustproof member 61 laminated with the touch sensor unit 59 and interposed between the bezel 60 and the protective glass 56 of the display monitor 2a on the front face of the display device 2, it is possible to prevent chalk power or dust from entering into the display device 2.

In the display system of the present embodiment, it is possible to fix the I/O unit 20 and the option slot unit 21 to the side end, opposite to the blackboard 3, aside the height 14a of the cover 14 in the rear face of the display device 2 in consideration of the predetermined standing position of a teacher or a presenter, wherein it is possible to expose the input/output terminals 22 and 36 of the units 20 and 21 to the exterior of the display device 2; that is, it is possible for each user to easily operate the input/output terminals 22 and 36 depending on the predetermined standing position of a teacher or a presenter. To fix the I/O unit 20 to either the right side end or the left side end on the planar part 14b, it is possible to determine the positioning by reversing the front and the rear as necessary; hence, it is possible to reliably expose the side face 20a having the input/output terminal 22 to the exterior, and it is possible to prevent the power cord 23 from interfering with other parts irrespective of the reversal of the front and the rear of the I/O unit 20 since the power cord 23 is not changed in terms of the position and the direction. To fix the option slot unit 21 to either the right side end or the left side end on the planar part 14b, it is possible to determine the positioning by reversing the front and the rear as necessary; hence, it is possible to reliably expose the side face 21a having the input/output terminal 36 to the exterior, and it is possible not to prevent air ventilation since the side face 21b having the air inlet 37 and the air outlet 38 are directed to the exterior even when the option slot unit 21 is positioned in either the right side end or the left side end.

Additionally, it is possible to determine the standing position of a teacher or a presenter based on the relationship between the standing position of a teacher or a presenter and the furnishings such as desks in a school room in advance; therefore, it is possible to produce the display system 1 by fixing the positions of the I/O unit 20, the option slot unit 21, the second and third cable covers 42 and 43 in either the right side or the left side from the height 14a. Irrespective of installing the parts in either the right side or the left side of the display system 1, it is possible to share and standardize the parts of the display system 1 by use of the same types of the I/O unit 20, the option slot unit 21, the second and third cable covers 42 and 43; hence, it is possible to easily manage parts while reducing the manufacturing cost.

When the positions of the I/O unit 20 and the option slot unit 21 are fixed to either the left side or the right side of the planar part 14b from the height 14a of the cover 14 in the rear face of the display device 2, it is possible to selectively arrange the second cable cover 42 and the third cable cover 43 in association with the first cable cover 41 so as to cover the wiring cords; hence, it is possible to prevent pupils or students from touching or playing with wiring cords.

Additionally, it is possible to prevent chalk powder or dust from entering into the speaker unit 49 since the dustproof sheet 52 and the bracket 45 having the output parts 46 with punching apertures are sequentially attached to the front face of the speaker unit 49 of the speaker device 19. Due to the vibration-proof sheet 51 attached to the front face of the speaker unit 49, it is possible to prevent the speaker unit 49 from generating noise irrespective of vibration occurring in the speaker device 19.

Moreover, it is possible to prevent chalk powder or dust from entering inside the display device 2 since the dustproof member 61 is interposed between the bezel 60 and the touch sensor unit 59 attached to the protective glass 56 of the display monitor 2a in the front face of the display device 2.

The present invention is not necessarily limited to the display system 1 of the foregoing embodiment; hence, it is possible to appropriately adopt any variations without changing the subject matter of the present invention. For example, it is possible for the present invention to solely use the display device 2 instead of the display system 1 of the foregoing embodiment. In this case, it is possible to install the I/O unit 20, the option slot unit 21, the second and third cable covers 42 and 43 in either the right side end or the left side end of the planar part 14b from the height 14a in the rear face of the display device 2 in consideration of the standing position of a teacher or a presenter. Thus, it is possible to demonstrate the same operation and effect as the foregoing embodiment.

The display system 1 and the display device 2 according to the foregoing embodiment are each designed such that the I/O unit 20, the option slot unit 21, the second and third cable covers 42 and 43 are positioned in either the right side or the left side of the planar part 14b from the height 14a formed in the center area of the rear cover 14; however, it is possible to apply the present invention to the display device 2 precluding the height 14a.

The air outlet 37 and the air inlet 38 are formed in the front face 21b of the option slot unit 21 positioned opposite to the planar part 14b of the cover 14. Instead, it is possible to form the air outlet 37 and the air inlet 38 in the other side face of the option slot unit 21 unconnected to the input/output terminal 36.

Additionally, it is possible to install either the I/O unit 20 or the option slot unit 21 in either side end of the cover 14. Alternatively, it is possible to install the units 20 and 21 in the opposite side ends of the cover 14. Moreover, it is possible to install another input/output unit, other than the I/O unit 20 and the option slot unit 21, in the side end of the cover 14.

The foregoing embodiment is designed such that the I/O unit 20 and the option slot unit 21 are connected to the input/output terminal 18 of the main unit formed in the rear face of the display device 2 via the wiring cords which are covered by the first, second, and third cable covers 41, 42, and 43; however, it is not necessary to arrange the wiring cords. In this case, it is possible to arrange a rod-like connection terminal with a convexo-concave engaging structure along the side faces, relative to the side faces 20a and 21a of the I/O unit 20 and the option slot unit 21, and to directly connect the connection terminal to the input/output terminal 18 of the main body. In this case, it is necessary to form a rod-like connection terminal, attached to the side face of the option slot unit 21, in a vertically symmetrical manner in such a manner that the connection terminal can be connected to the input/output terminal 18 of the main body even when the upper and lower faces thereof are reversed. In this configuration, it is possible to omit the first, second, and third cable covers 41, 42, and 43.

### INDUSTRIAL APPLICABILITY

The present invention provides a display device and a display system having a display device whose input/output terminals are directed to the exterior even when both the I/O unit 20 and the option slot unit 21 are selectively fixed to either the right side end or the left side end in the rear face of the display device.

### REFERENCE SIGNS LIST

1 display system
2 display device
2a display monitor
3 blackboard
12 whiteboard
13 control part
18 input/output terminal of a main body
19 speaker device
20 I/O unit
21 option slot unit
22, 36 input/output terminal
23 power cord
24 fixing metal member
25 bolt
37 air outlet
38 air inlet
41 first cable cover
42 second cable cover
43 third cable cover
45 bracket
46 output part
49 speaker unit
51 vibration-proof sheet
52 dustproof sheet
59 touch sensor unit
60 bezel
61 dustproof member

1. A display device comprising: a display part disposed in a front face; a control part which is disposed in a rear face to drive the display part; and a reversible input/output unit, having an input/output terminal, which is detachably and selectively attached to either a first side end or a second side end in a planar part of the rear face, wherein the input/output terminal of the input/output unit is directed to an exterior irrespective of a position of the input/output unit.

2. (canceled)

3. The display device according to claim 1, further comprising a reversible option slot unit adjacent to the input/output unit.

4. The display device according to claim 1, wherein a cover used to cover a wiring cord of the input/output unit connectable to the control part is selectively attached to the rear face at an arbitrary position depending on the position of the input/output unit.

5. (canceled)

6. The display device according to claim 3, wherein an air inlet and an air outlet are formed in a predetermined face of the option slot unit opposite to the planar part of the rear face.

7. A display system comprising: a display device including a display part disposed in a front face and a control part which is disposed in a rear face to drive the display part; a display board juxtaposed with the display device; and a reversible input/output unit, having an input/output terminal, which is selectively and detachably attached to either a first side end or a second side end in a planar part of the rear face, wherein the input/output unit is positioned opposite to the display board in such a way that the input/output terminal is directed to an exterior irrespective to a position of the input/output unit.

8. (canceled)

9. The display system according to claim 7, further comprising a reversible option slot unit adjacent to the input/output unit.

10. The display system according to claim 7, further comprising a cover used to cover a wiring cord of the input/output unit connectable to the control part is selectively attached to the rear face at an arbitrary position depending on the position of the input/output unit.

11. (canceled)

12. The display system according to claim 9, wherein an air inlet and an air outlet are formed in a predetermined face of the option slot unit opposite to the planar part of the rear face, and wherein the option slot unit is selectively attached to either the first side end or the second side end by vertically reversing an upper face and a lower face thereof.
